(19) United States
(12) Patent Application Publication
(10) Pub. No.: US 2013/0240802 A1
(43) Pub. Date: Sep. 19, 2013

(54) OXIDE FOR SEMICONDUCTOR LAYER OF THIN-FILM TRANSISTOR, SPUTTERING TARGET, AND THIN-FILM TRANSISTOR

(71) Applicants: Aya Miki, Kobe-shi (JP); Shinya Morita, Kobe-shi (JP); Toshihiro Kugimiya, Kobe-shi (JP); Satoshi Yasuno, Kobe-shi (JP); Jae Woo Park, Seongnam-city (KR); Je Hun Lee, Seoul-city (KR); Byung Du Ahn, Hwaseong-city (KR)

(72) Inventors: Aya Miki, Kobe-shi (JP); Shinya Morita, Kobe-shi (JP); Toshihiro Kugimiya, Kobe-shi (JP); Satoshi Yasuno, Kobe-shi (JP); Jae Woo Park, Seongnam-city (KR); Je Hun Lee, Seoul-city (KR); Byung Du Ahn, Hwaseong-city (KR)

(73) Assignees: Samsung Display Co., Ltd., Yongin-city ,Gyeonggi-do (KR); KABUSHIKI KAISHA KOBE SEIKO SHO (Kobe Steel ,Ltd.), Kobe-shi ,Hyogo (JP)

(21) Appl. No.: 13/989,948

(22) PCT Filed: Nov. 28, 2011
(86) PCT No.: PCT/JP2011/077319

§ 371 Date: May 28, 2013

(30) Foreign Application Priority Data
Nov. 26, 2010 (JP) 2010-264325
Jan. 18, 2011 (JP) 2011-008321
Sep. 6, 2011 (JP) 2011-194408

(51) Int. Cl. H01L 29/786

(52) U.S. Cl. CPC H01L 29/7869
USPC 252/519.15; 423/326; 423/594.3; 423/600; 423/594.8; 423/594.9; 204/298.13

(57) ABSTRACT

This oxide for a semiconductor layer of a thin-film transistor contains Zn, Sn and In, and at least one type of element (X group element) selected from an X group comprising Si, Hf, Ga, Al, Ni, Ge, Ta, W and Nb. The present invention enables a thin-film transistor oxide that achieves high mobility and has excellent stress resistance (negligible threshold voltage shift before and after applying stress) to be provided.

### TECHNICAL FIELD

The present invention relates to an oxide for a semiconductor layer of a thin-film transistor to be used display devices such as a liquid crystal display, an organic EL display; a sputtering target for forming a film of the oxide; and a thin-film transistor.

### BACKGROUND ART

As compared with widely used amorphous silicon (a-Si), an amorphous (noncrystalline) oxide semiconductor has high carrier mobility, a high optical band gap, and film formability at low temperature and, therefore, has been highly expected to be applied for next generation displays which are required to have a large size, high resolution, and high-speed drive, resin substrates which has low heat resistance, and the like.

Of oxide semiconductors, an amorphous oxide semiconductor containing indium, gallium, zinc, and oxygen (In—Ga—Zn—O, hereinafter also referred to as “IGZO”), which has a considerably high carrier mobility, is particularly preferably used. For example, Non-Patent Documents 1 and 2 disclose a thin-film transistor (TFT) including a thin oxide semiconductor film of In:Ga:Zn=1.1:1.1:0.9 (atomic % ratio) as a semiconductor layer (active layer). Patent Document 1 also discloses an amorphous oxide containing elements, such as In, Zn, Sn, Ga, and the like, and Mo, where Mo has an atomic composition ratio of 0.1 to 5 atomic % with respect to the total number of metal atoms in the amorphous oxide. A TFT including an active layer of IGZO doped with Mo is disclosed in the example of Patent Document 1.

### PRIOR ART DOCUMENT

### Patent Document

Patent Document 1: JP-A-2009-164393

### Non-Patent Document

Non-patent Document 1: solid physics, vol 44, P621 (2009)
Non-patent Document 2: Nature, vol 432, P488 (2004)

### SUMMARY OF THE INVENTION

### Problems to be Solved by the Invention

In the case where an oxide semiconductor is used as a semiconductor layer for a thin-film transistor, the oxide semiconductor is required not only to have a high carrier concentration but also to be excellent in switching properties (transistor characteristics) of TFT. Specifically, the oxide semiconductor is required to satisfy (1) high ON-current (maximum drain current when positive voltage is applied to a gate electrode and a drain electrode); (2) low OFF-current (drain current when negative voltage is applied to a gate electrode and positive voltage is applied to a drain electrode); (3) low SS value (Subthreshold Swing, gate voltage required to increase drain current by one digit); (4) stability of threshold with the lapse of time (voltage at which drain current starts flowing when positive voltage is applied to a drain electrode and either positive or negative voltage is applied to a gate voltage, which is also referred to as threshold voltage) (it means uniform even in in-place of substrate); (5) a high mobility; (6) a small change in above mentioned properties at the time of light irradiation, and the like. The inventors of the present invention have investigated the above properties of ZTO containing Mo semiconductor described in previously mentioned Patent Document 1. As a result, they have found that it showed degradation of ON-current and elevation of SS value compared with that of ZTO.

Furthermore, a TFT using an oxide semiconductor layer of IGZO and ZTO, and the like are required to be excellent in resistance (stress stability) to voltage application and stress of light irradiation, and the like. For example, when positive voltage or negative voltage is continuously applied to gate voltage or when light in a blue emitting band in which light absorption starts is continuously irradiated, the threshold voltage is changed (shifted) considerably, and it is pointed out that because of that, the switching properties of the TFT are changed. And for example, at the time of driving a liquid crystal panel or at the time of lighting a pixel by applying negative bias to a gate electrode, and the like, the TFT is irradiated with light leaked out from a liquid crystal cell and this light gives stress to the TFT to cause deterioration of the properties such as elevation of the OFF-current, shift of the threshold voltage, and increase of the SS value, and the like. Particularly, shift of the threshold voltage leads to lowering of reliability in a display device itself such as a liquid crystal display or an organic EL display equipped with TFT, and, therefore, it has been desired to improve the stress stability (small change before and after stress tests).

The present invention has been made in view of the above situation. It is an object of the present invention to provide an oxide for a thin-film transistor, which has a high mobility and excellent stress stability (a small threshold voltage shift between before and after stress tests), a thin-film transistor including the oxide, and a sputtering target for use in forming the oxide.

### Means for Solving the Problems

An oxide for semiconductor layer of a thin-film transistor of the present invention which can be solved above problems is summarized in that a oxide to be used for the semiconductor layer of the transistor, wherein the oxide contains Zn, Sn and In; and at least one kind element (X-group element) selected from a X-group of consisting of Si, Hf, Ga, Al, Ni, Ge, Ta, W and Nb.

In a preferred embodiment of the present invention, in the case where the content (atomic %) of metal elements contained in the oxide is defined as [Zn], [Sn], and [In] respectively, the content satisfies below expressions (1) to (3).

[In]/([In]+[Zn]+[Sn])≧−0.53×[Zn]/([Zn]+[Sn])+0.36 (1)

[In]/([In]+[Zn]+[Sn])≧2.28×[Zn]/([Zn]+[Sn])−2.01 (2)

[In]/([In]+[Zn]+[Sn])≦1.1×[Zn]/([Zn]+[Sn])−0.32 (3)

In a preferred embodiment of the present invention, in the case where the content (atomic %) of metal elements contained in the oxide is defined as [Zn], [Sn], [In], and [X] respectively, the ratio of [Zn] to ([Zn]+[Sn]) is represented by <Zn>, and the ratio of each of the X-group element to ([Zn]+[Sn]+[In]+[X]) is represented by {X} respectively, the content satisfies below expression (4).

[−89×<Zn>+74]×[In]/([In]+[Zn]+[Sn])+25×<Zn>−6.5−75×{Si}−120×{Hf}−6.5×{Ga}−123×{Al}−15×{Ni}−244×{Ge}−80×{Ta}−580×{W}−160×{Nb}≧5 (4)

wherein, each means

<Zn>=[Zn]/([Zn]+[Sn]),

{Si}=[Si]/([Zn]+[Sn]+[In]+[X]),

{Hf}=[Hf]/([Zn]+[Sn]+[In]+[X]),

{Ga}=[Ga]/([Zn]+[Sn]+[In]+[X]),

{Al}=[Al]/([Zn]+[Sn]+[In]+[X]),

{Ni}=[Ni]/([Zn]+[Sn]+[In]+[X]),

{Ge}=[Ge]/([Zn]+[Sn]+[In]+[X]),

{Ta}=[Ta]/([Zn]+[Sn]+[In]+[X]),

{W}=[W]/([Zn]+[Sn]+[In]+[X]),

{Nb}=[Nb]/([Zn]+[Sn]+[In]+[X])

In a preferred embodiment of the present invention, in the case where the content (atomic %) of metal elements contained in the oxide is defined as [Zn], [Sn], [In], and [X], the content satisfies below expression (5).

0.0001≦[X]/([Zn]+[Sn]+[In]+[X]) (5)

A thin-film transistor having the above oxide as a semiconductor layer of the thin-film transistor is included in the present invention.

The density of the above semiconductor layer is preferably 5.8 g/cm³ or higher.

Also, a sputtering target of the present invention is a sputtering target for forming the above oxide, wherein the sputtering target contains Zn, Sn and In; and at least one kind element (X-group element) selected from a X-group of consisting of Si, Hf, Ga, Al, Ni, Ge, Ta, W and Nb, in the case where the content (atomic %) of metal elements contained in the sputtering target is defined as [Zn], [Sn], and [In] respectively, the content satisfies below expressions (1) to (3).

[In]/([In]+[Zn]+[Sn])≧−0.53×[Zn]/([Zn]+[Sn])+0.36 (1)

[In]/([In]+[Zn]+[Sn])≧2.28×[Zn]/([Zn]+[Sn])−2.01 (2)

[In]/([In]+[Zn]+[Sn])≦1.1×[Zn]/([Zn]+[Sn])−0.32 (3)

In a preferred embodiment of the present invention, in the case where the content (atomic %) of metal elements contained in the sputtering target is defined as [Zn], [Sn], [In], and [X] respectively, the ratio of [Zn] to ([Zn]+[Sn]) is represented by <Zn>, and the ratio of each of the X-group element to ([Zn]+[Sn]+[In]+[X]) is represented by {X} respectively, the content satisfies below expression (4).

[−89×<Zn>+74]×[In]/([In]+[Zn]+[Sn])+25×<Zn>−6.5−75×{Si}−120×{Hf}−6.5×{Ga}−123×{Al}−15×{Ni}−244×{Ge}−80×{Ta}−580×{W}−160×{Nb}≧5 (4)

wherein, each means

<Zn>=[Zn]/([Zn]+[Sn]),

{Si}=[Si]/([Zn]+[Sn]+[In]+[X]),

{Hf}=[Hf]/([Zn]+[Sn]+[In]+[X]),

{Ga}=[Ga]/([Zn]+[Sn]+[In]+[X]),

{Al}=[Al]/([Zn]+[Sn]+[In]+[X]),

{Ni}=[Ni]/([Zn]+[Sn]+[In]+[X]),

{Ge}=[Ge]/([Zn]+[Sn]+[In]+[X]),

{Ta}=[Ta]/([Zn]+[Sn]+[In]+[X]),

{W}=[W]/([Zn]+[Sn]+[In]+[X]),

{Nb}=[Nb]/([Zn]+[Sn]+[In]+[X])

In a preferred embodiment of the present invention, in the case where the content (atomic %) of metal elements contained in the sputtering target is defined as [Zn], [Sn], [In], and [X], the content satisfies below expression (5).

0.0001≦[X]/([Zn]+[Sn]+[In]+[X]) (5)

### Effects of the Invention

With the oxide of the present invention, a thin-film transistor having a high mobility and excellent stress stability (a smaller threshold voltage shift between before and after stress tests) can be provided. As a result, a display device, which includes the thin-film transistor, has a greatly improved level of reliability against light irradiation.

### BRIEF DESCRIPTION OF THE DRAWINGS

FIG. 1 is a schematic cross-sectional view for illustrating a thin-film transistor having a present inventive oxide semiconductor.

FIG. 2 is a graph showing a region, which satisfies a range of expressions (1) to (3) defined in the present invention.

### MODE FOR CARRYING OUT THE INVENTION

The present inventors have extensively studied an oxide containing Zn, Sn, and In (hereinafter also represented by “IZTO”) in order to improve TFT characteristics and stress stability of a TFT including an active layer (semiconductor layer) which is formed of that oxide. As a result, the present inventors have found that the desired object is achieved by using, as a semiconductor layer of a TFT, an oxide semiconductor containing at least one kind element selected from the X-group consisting of Si, Hf, Ga, Al, Ni, Ge, Ta, W and Nb in IZTO, and completed the present invention. As shown in examples described below, a TFT having an oxide semiconductor containing an element (X-group element) belonging to the above-mentioned X-group has been found to be significantly excellent in TFT characteristics (specifically, a high mobility, a high ON current, a low SS value, and a small absolute value of a threshold voltage (Vth) in the vicinity of 0 V) and a small change in transistor characteristics between before and after stress tests (specifically, a smaller change rate (ΔVth) of Vth after stress test of light irradiation and negative bias).

That is, the oxide for a semiconductor layer of TFT of the present invention has a feature of containing Zn, Sn, and In; as well as at least one kind element (X-group element) selected from the X-group consisting of Si, Hf, Ga, Al, Ni, Ge, Ta, W and Nb. In this specification, the oxide of the present invention may be represented by (IZTO)—X.

(X-Group Element)

The above X-group element, which is a most characteristic feature of the present invention, have been selected as elements which effectively reduce formation of electron-hole pairs during light irradiation by, for example, reducing interface traps in the vicinity of the gate insulating film or expanding the band gap and the like, by the present inventors based on numerous preliminary experiments. The addition of the X-group element significantly improves stress stability to light. The experiments have shown that the addition of the X-group element does not cause problems, such as etching failure during wet etching and the like. The X-group element has different actions (different levels of exhibition of the effect), depending on the type(s) of the X-group element. The X-group element may be added singly or in combination of two or more.

Although the detailed mechanism that explains why the addition of the X-group element improves the characteristics is unclear, it is inferred that the X-group element has the effect of lowering the trap level in the oxide semiconductor or at the interface between the oxide semiconductor and the insulating layer or reducing the life. Therefore, it is inferred that even when light irradiation is applied, carriers trapped due to the light irradiation are reduced, whereby generation of a current during the light irradiation is prevented, and therefore, variations in the transistor characteristics between the presence and absence of light irradiation is reduced.

The content of the X-group element preferably satisfies expression (4) described below, where the content (atomic %) of the metal elements contained in the oxide of the present invention is represented by [Zn], [Sn], [In], and [X], the ratio of [Zn] to ([Zn]+[Sn]) is represented by <Zn>, and the ratio of each of the X-group element to ([Zn]+[Sn]+[In]+[X]) is represented by {X}. In expression (4) below, [X] represents the total amount of the X-group element (if only single X-group element is contained, [X] represents the amount of the single X-group element (atomic %), and if two or more X-group element are contained, [X] represents the total amount of the X-group element (atomic %)).

[−89×<Zn>+74]×[In]/([In]+[Zn]+[Sn])+25×<Zn>−6.5−75×{Si}−120×{Hf}−6.5×{Ga}−123×{Al}−15×{Ni}−244×{Ge}−80×{Ta}−580×{W}−160×{Nb}≧5 (4)

wherein, each means

<Zn>=[Zn]/([Zn]+[Sn]),

{Si}=[Si]/([Zn]+[Sn]+[In]+[X]),

{Hf}=[Hf]/([Zn]+[Sn]+[In]+[X]),

{Ga}=[Ga]/([Zn]+[Sn]+[In]+[X]),

{Al}=[Al]/([Zn]+[Sn]+[In]+[X]),

{Ni}=[Ni]/([Zn]+[Sn]+[In]+[X]),

{Ge}=[Ge]/([Zn]+[Sn]+[In]+[X]),

{Ta}=[Ta]/([Zn]+[Sn]+[In]+[X]),

{W}=[W]/([Zn]+[Sn]+[In]+[X]),

{Nb}=[Nb]/([Zn]+[Sn]+[In]+[X])

Above expression (4) is used to calculate an index for obtaining a high mobility and has been identified based on numerous preliminary experiments. Although above expression (4) includes all elements contained in the oxide of the present invention, the main elements of expression (4) are In, which significantly contributes to an improvement in the mobility, and the X-group element, which has a negative action to the mobility. As described above, the addition of the X-group element tends to improve the stress stability and decrease the mobility. Therefore, in view of the mobility in particular, expression (4) is prepared to define the upper limit of the content of the X-group element below which the mobility can be maintained high.

As shown in examples described below, the value (calculated value) on the left side of above expression (4) mostly agrees with the saturated mobility (actual measured value), and as the value (calculated value) on the left side of above expression (4) increases, the saturated mobility increases. Strictly speaking, expressions (1) and (2) described below also relate to the saturated mobility, and when these expressions fall within respective preferred ranges of the present invention, above expression (4) has substantially a high correlation with the saturated mobility. Although the value (calculated value) on the left side of expression (4) is negative when the amount of the X-group element added takes some values (e.g., Nos. 40 and 49 in Table 2 described below), the negative numeric value itself does not have a meaning (the mobility cannot take a negative value), and indicates that the example having such a negative value has a low mobility.

Furthermore, content [X] of X-group element preferably satisfies expression (5) described below.

0.0001≦[X]/([Zn]+[Sn]+[In]+[X]) (5)

Above expression (5) defines a preferable proportion of [X] (hereinafter also abbreviated to “[X] ratio”) with respect to the total amount ([Zn]+[Sn]+[In]+[X]) of all the metal elements contained in the oxide of the present invention. When the [X] ratio is small (i.e., the content of the X-group element is small), a sufficient level of the stress stability improving effect is not obtained. More preferably, the [X] ratio is 0.0005 or higher. Specifically, the X-group element has different levels of the action (different levels of exhibition of the effect). Therefore, strictly speaking, the [X] ratio is preferably controlled as appropriate, depending on the type(s) of the X-group element(s).

Of the above X-group element, Nb, Si, Ge, and Hf are preferable in order to improve the stress stability or the like, more preferably Nb and Ge.

The X-group element used in the present invention has been described.

Next, the metals (Zn, Sn, and In) which are base components contained in the oxide of the present invention will be described. With reference to these metals, the ratio of these metals is not particularly limited as long as the oxide containing these metals has an amorphous phase and exhibits semiconductor characteristics. However, it has been found that, in order to obtain the oxide which provides excellent TFT characteristics and excellent stress stability, it is preferable to use, in the TFT semiconductor layer, the oxide in which the composition ratio of the metal elements in IZTO is appropriately controlled.

Specifically, the present inventors have conducted numerous preliminary experiments on the influence of In, Zn, and Sn on the TFT characteristics and the stress stability to find the followings: (a) although In is an element that contributes an improvement in the mobility, a large amount of In added leads to a decrease in the stability (resistance) against light stress or is likely to make the TFT conductive; (b) on the other hand, although Zn is an element that improves the stability against light stress, a large amount of Zn added leads to a sharp decrease in the mobility or a decrease in the TFT characteristics or the stress stability; and (c) although, similar to Zn, Sn is an element that effectively improves the stability against light stress, and the addition of Sn suppresses the IZTO from becoming conductive, a large amount of Sn added leads to a decrease in the mobility or a decrease in the TFT characteristics or the stress stability.

Based on these findings, the present inventors have further studied and found the following. That is, in the case where content (atomic %) of metal elements contained in an oxide is expressed as [Zn], [Sn], and [In] respectively, and preferably, the ratio of [In] represented by [In]/([In]+[Zn]+[Sn]) (hereinafter also simply abbreviated to “In ratio”) in relation to the ratio of [Zn] represented by [Zn]/([Zn]+[Sn]) (hereinafter also simply abbreviated to “Zn ratio”) satisfies all expressions (1) to (3) below, the oxide has satisfactory characteristics.

[In]/([In]+[Zn]+[Sn])≧−0.53×[Zn]/([Zn]+[Sn])+0.36 (1)

[In]/([In]+[Zn]+[Sn])≧2.28×[Zn]/([Zn]+[Sn])−2.01 (2)

[In]/([In]+[Zn]+[Sn])≦1.1×[Zn]/([Zn]+[Sn])−0.32 (3)

FIG. 2 shows regions of above expressions (1) to (3). A hatched portion of FIG. 2 indicates a region in which all expressions (1) to (3) above are satisfied. In FIG. 2, characteristics results of examples described below are also plotted. Some results that fall within the hatched range of FIG. 2 are satisfactory in terms of all of saturated mobility, TFT characteristics, and stress stability (circles in FIG. 2), while the other results that do not fall within the hatched portion of FIG. 2 (i.e., the results do not satisfy all of above expressions (1) to (3)) have at least one of the above properties that is reduced (crosses in FIG. 2).

Of above expressions (1) to (3), expressions (1) and (2), which mainly relate to the mobility, have been prepared based on numerous preliminary experiments to define the In ratio for achieving a high mobility in association with the Zn ratio.

Expression (3), which mainly relates to an improvement in the stress stability and the TFT characteristics (TFT stability), has been prepared based on numerous preliminary experiments to define the In ratio for achieving high light stress stability in association with the Zn ratio.

Specifically, it has been found that most of the results which do not satisfy all of expressions (1) to (3), furthermore do not satisfy expression (4) mentioned before have drawbacks described below.

Firstly, assuming that expression (4) is satisfied, IZTOs which satisfy expression (2) and do not satisfy expressions (1) and (3) have larger Sn ratios (i.e., smaller Zn ratios). Therefore, for such IZTOs, although the mobility tends to increase, the S value or the Vth value tends to increase, and therefore, the TFT characteristics and the stress stability tend to decrease. Therefore, the desired characteristics are not obtained (see, for example, Nos. 1, 8, 34 in the examples below).

Similarly, assuming that expression (4) is satisfied, IZTOs which satisfy expressions (1) and (3) and do not satisfy expression (2) have larger Zn ratios (i.e., smaller Sn ratios). Therefore, for such IZTOs, the mobility tends to sharply decrease, and the S value or the Vth value tends to significantly increase, and therefore, the TFT characteristics and the stress stability tend to decrease. Therefore, the desired characteristics are not obtained (see, for example, Nos. 2, 9, 35, 51 in the examples below).

Similarly, assuming that expression (4) is satisfied, for IZTOs which satisfy expressions (1) and (2) and do not satisfy expression (3) and which have larger In ratios, the mobility tends to increase, and the stress stability tends to decrease. Therefore, the desired characteristics are not obtained (see, for example, No. 22 in the examples below).

On the other hand, for IZTOs which satisfy expressions (1) to (3) and do not satisfy expression (4), the mobility tends to decrease. Therefore, the desired characteristics are not obtained (see, for example, Nos. 40 and 49 in the examples below).

No. 13 in the examples below is an example which does not satisfy expression (4) or expression (3). Because No. 13 does not satisfy expression (4), No. 13 had a lower mobility. In addition, although No. 13 does not satisfy expression (3), the stress stability meets the pass criterion (ΔVth is below the line, i.e., −15 or less) because the amount of Hf of X-group element added was relatively large (the [X] ratio=0.10).

No. 50 in the examples below is an example which does not satisfy expression (4) and does not satisfy expression (1) or expression (3). Although No. 50 has a high mobility, the TFT characteristics and the stress stability tend to decrease because No. 50 does not satisfy expression (3).

The components In, Sn, and Zn in the oxide for the semiconductor layer of a TFT according to the present invention preferably satisfy the above requirements. More preferably, the ratio of [In] to ([Zn]+[Sn]+[In]) is 0.05 or higher. As described above, In is an element that increases the mobility. When the ratio of [In] represented by expression (1) is less than 0.05, the above effect is not effectively exhibited. More preferably, the In ratio is 0.1 or higher. On the other hand, if the In ratio is excessively high, the stress stability decreases or the oxide is likely to become conductive. Therefore, mostly, the In ratio is preferably 0.5 or less.

The oxide of the present invention is described above.

The above oxide is preferably formed in a film using a sputtering target (which may be hereinafter referred to as a “target”) with a sputtering method. The oxide can be formed by a chemical film formation method such as a coating method; however, it is possible to easily form a thin film excellent in film in-plane uniformity of components and film thickness according to the sputtering method.

As a target to be used in the sputtering method, there may preferably be used a target containing the elements described above and having the same composition as that of a desired oxide, thereby making it possible to form a thin film having a desired component composition without a possibility of a composition gap. More specifically, a target containing Zn, Sn and In; as well as at least one kind element selected from the X-group (X-group element) consisting of Si, Hf, Ga, Al, Ni, Ge, Ta, W and Nb; and the content (atomic %) of metal elements contained in the sputtering target defined as [Zn], [Sn] and [In] respectively satisfies above expressions (1) to (3) is used as the target. Preferably the target satisfies above expression (4), in the case where the content (atomic %) of X-group element contained in the above target is represented by [X].

Alternatively, film formation may be carried out by a co-sputtering method for simultaneously discharging two targets with different compositions and consequently, a film with a desired composition can be obtained by co-sputtering targets such as In₂O₃, ZnO, SnO₂, and the like or a target of mixture thereof.

The above-mentioned targets can be produced by, for example, a powder sintering process method.

In the case of sputtering the above-mentioned target, it is preferable that the substrate temperature is adjusted to room temperature and the concentration of oxygen is controlled properly for the execution. The concentration of oxygen may be controlled properly in accordance with the configuration of a sputtering apparatus and the target composition, and the like, and it is preferable to add oxygen in such a manner that the carrier concentration of the oxide semiconductor is approximately 10¹⁵ to 10¹⁶ cm⁻³. The concentration of oxygen in examples mentioned below is controlled such that it satisfies O₂/(Ar+O₂)=2% in addition flow ratio.

Also, in the case where the above-mentioned oxide is used as the semiconductor layer of the TFT, the density of the oxide semiconductor layer is preferably 5.8 g/cm³ or higher (described below), and in order to form a film of such an oxide, it is preferable to properly control the gas pressure during sputtering, the power input to a sputtering target, the substrate temperature, and the like. For example, if the gas pressure is made low at the time of film formation, scattering of sputtered atoms one another can be prevented and it is supposed to be possible to form a compact (highly dense) film, and due to that, it is good as the entire gas pressure at the time of film formation is low to an extent that the discharge for sputtering is stabilized, and the pressure may be controlled preferably in a range of approximately 0.5 to 5 mTorr and more preferably in a range of 1 to 3 mTorr. Also, it is good as the power input is high, and it is recommended to set the power input of DC or RF to approximately 2.0 W/cm² or higher. It is also good as the substrate temperature at the time of film formation is high, and it is recommended to set the temperature to a range around room temperature to 200° C.

The film thickness of the oxide formed into a film as described above is preferably 30 nm or more and 200 nm or less, and more preferably 30 nm or more and 80 nm or less.

The present invention also encompasses a TFT having the above-mentioned oxide as a semiconductor layer of the TFT. The TFT may have at least a gate electrode, a gate insulator layer, a semiconductor layer of the above-mentioned oxide, a source electrode, and a drain electrode on a substrate, and its configuration is not particularly limited as long as it is used commonly.

Herein, the density of the above oxide semiconductor layer is preferably 5.8 g/cm³ or higher. Tithe density of the oxide semiconductor layer is high, defects in the film are decreased to improve the film quality, and also since the interatomic distance is narrowed, the electron field-effect mobility of a TFT element is significantly increased and the electric conductivity becomes high and the stability to stress by light irradiation is improved. The density of the above oxide semiconductor layer is good as it is higher, and it is more preferably 5.9 g/cm³ or more and further preferably 6.0 g/cm³ or more. The density of the oxide semiconductor layer is measured by a method described in examples below.

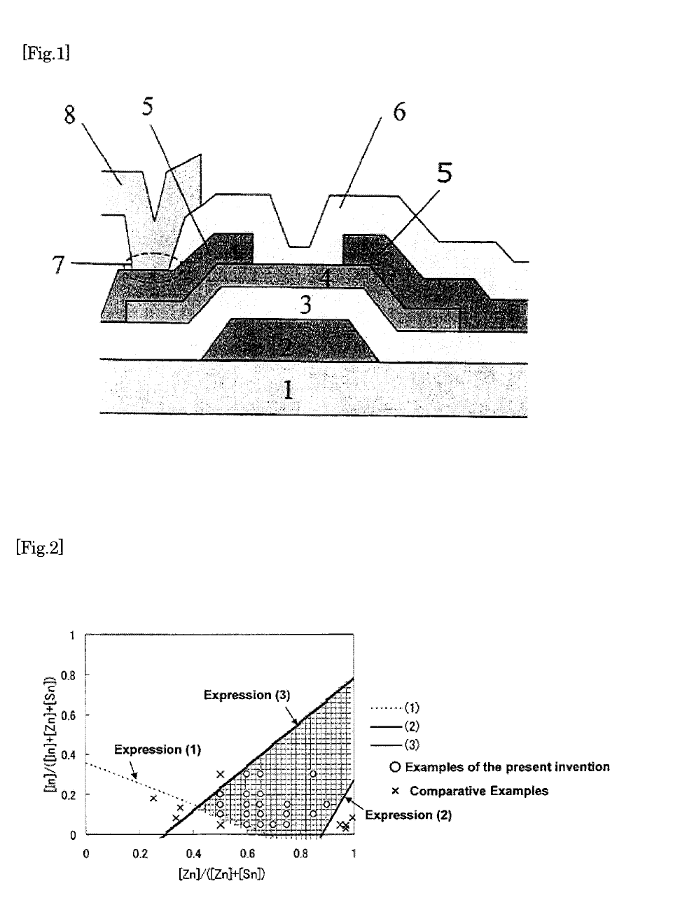

Hereinafter, by referring to FIG. 1, embodiments of a method for producing the above-mentioned TFT will be described. FIG. 1 and the following production method describe one example of preferred embodiments of the present invention, and it is not intended that the present invention be limited thereto. For example, FIG. 1 shows a TFT with a bottom gate type structure, however, the TFT is not limited thereto, and the TFT may be a top gate type TFT having a gate insulator layer and a gate electrode successively on an oxide semiconductor layer.

As shown in FIG. 1, a gate electrode 2 and a gate insulator layer 3 are formed on a substrate 1 and an oxide semiconductor layer 4 is formed further thereon. A source-drain electrode 5 is formed on the oxide semiconductor layer 4 and a passivation layer (insulator layer) 6 is formed thereon and a transparent conductive film 8 is electrically connected to the drain electrode 5 through a contact hole 7.

A method for forming the gate electrode 2 and the gate insulator layer 3 on the substrate 1 is not particularly limited and methods commonly used can be adopted. Also, the kinds of the gate electrode 2, and the gate insulator layer 3 are not also particularly limited and widely used ones can be used. For example, metals such as Al and Cu with low electric resistance and their alloys can be preferably used for the gate electrode 2. Also, typical examples of the gate insulator layer 3 include a silicon oxide film, a silicon nitride film, and a silicon oxynitride film, and the like. Additionally, metal oxides such as TiO₂, Al₂O₃ and Y₂O₃ and those formed by layering them can be also used.

Next, the oxide semiconductor layer 4 is formed. The oxide semiconductor layer 4 is preferable to be formed into a film by, as described above, a DC sputtering method or an RF sputtering method using a sputtering target with the same composition as that of the thin film. Alternatively, the film formation may be carried out by a co-sputtering method.

After wet etching, the oxide semiconductor layer 4 is subjected to patterning. It is preferable to carry out heat treatment (pre-annealing) for improving the film quality of the oxide semiconductor layer 4 immediately after the patterning and accordingly, the ON-current and electron field-effect mobility, which are transistor characteristics, are increased and the transistor performance is improved. The preferable pre-annealing condition is, for example, temperature: about 250 to 350° C., time: about 15 to 120 minutes.

After pre-annealing, the source-drain electrode 5 is formed. The kind of the source-drain electrode 5 is not particularly limited and widely used ones can be used. For example, similarly to the gate electrode, metals such as Al and Cu and their alloys may be used, or pure Ti as described in examples below may be used, or further laminated structure of metals and the like may be used.

A method for forming the source-drain electrode 5 may be carried out by, for example, forming a metal thin film by a magnetron sputtering method and forming the metal thin film into the source-drain electrode 5 by a lift-off method. Alternatively, there is a method for forming the source-drain electrode 5 by previously forming a prescribed metal thin film by a sputtering method and thereafter forming the electrode by patterning, not forming the electrode by the lift-off method as described above; however, this method deteriorates the transistor characteristics since the oxide semiconductor layer is damaged at the time of etching of the electrode. Therefore, in order to avoid such problems, a method including previously forming a passivation layer on the oxide semiconductor layer, and subsequently forming the electrode by patterning is adopted, and this method is used in examples described below.

Next, the passivation layer (insulator layer) 6 is formed on the oxide semiconductor layer 4 by a CVD (Chemical Vapor Deposition) method. The surface of the oxide semiconductor layer 4 is converted easily to be conductive by plasma-induced damage due to CVD (it is supposedly attributed to that oxygen deficiency formed on the surface of the oxide semiconductor becomes an electron donor), and in order to avoid the problems, N₂O plasma irradiation is carried out before film formation of the passivation layer in examples described below. The condition described in the following document is adopted as the N₂O plasma irradiation condition.

J. Park, et. al, Appl. Phys. Lett., 93, 053505 (2008).

Next, according to a common method, the transparent conductive film 8 is electrically connected to the drain electrode 5 through the contact hole 7. The kinds of the transparent conductive film and drain electrode are not particularly limited, and those which are used commonly can be used. As the drain electrode, materials exemplified for the above-mentioned source-drain electrodes can be used.

### EXAMPLES

Below, by way of examples, the present invention will be more specifically described. However, the present invention is not limited by the following examples. It is naturally understood that modifications may be properly made and practiced within the scope adaptable to the meaning described above and below. All of these are included in the technical scope of the present invention.

### Example 1

According to the above-mentioned method, a thin-film transistor (TFT) shown in FIG. 1 was produced and the TFT characteristics and the stress stability were evaluated.

First, a Ti thin film with a thickness of 100 nm as a gate electrode and a gate insulator layer SiO₂ (200 nm) were successively formed on a glass substrate (EAGLE 2000 manufactured by Corning Incorporated, diameter 100 mm×thickness 0.7 mm). The gate electrode was formed by using a pure Ti sputtering target by a DC sputtering method in conditions as follows: film formation temperature: room temperature, film formation power: 300 W, carrier gas: Ar, and gas pressure: 2 mTorr. Also, the gate insulator layer was formed by a plasma CVD method in conditions as follows: carrier gas: mixed gas of SiH₄ and N₂O, film formation power: 100 W, and film formation temperature: 300° C.

Next, oxide (IZTO+X) thin films with various compositions as described in Table 1 and Table 2 were formed by a sputtering method using sputtering targets (described below). An apparatus used for the sputtering was “CS-200” manufactured by ULVAC, Inc. and the sputtering conditions were as follows.

Substrate temperature: room temperature

Gas pressure: 5 mTorr

Oxygen partial pressure: O₂/(Ar+O₂)=2%

Film thickness: 50 nm

Size of target used: φ 4 inch×5 mm

Input power (DC): 2.55 W/cm²

IZTO films having different compositions were formed by RF sputtering using a sputtering target of In₂O₃ and a sputtering target having different ZnO and Zn/Sn ratios. Also, a ZTO film (conventional example) was formed by co-sputtering in which electric discharge is simultaneously applied to an oxide target (Zn—Sn—O) having a ratio of Zn:Sn of 6:4 (atomic % ratio) and an oxide target of ZnO. Also, a thin IZTO+X oxide film which contains the X-group element in IZTO was formed by co-sputtering in which electric discharge is simultaneously applied to two sputtering targets having different compositions.

The contents of the respective metal elements in the oxide thin films obtained in this manner were analyzed by XPS (X-ray Photoelectron Spectroscopy) method.

After the thin oxide films were thus formed as above, patterning was performed by photolithography and wet etching. The etchant used was “ITO-07N” manufactured by Kanto Chemical Co., Inc. In this example, the wet etchability of the thin oxide films used in the experiment was evaluated by optical microscopic observation. The evaluation results show that residue did not occur due to wet etching for all the compositions used in the experiment, and all the thin oxide films were appropriately etched.

After the patterning, pre-annealing treatment was performed on the oxide films to improve the film quality thereof. The pre-annealing was performed at 350° C. under atmospheric pressure for 1 hour.

Next, a source-drain electrode was formed by a lift-off method using pure Ti. Specifically, after patterning was carried out using a photoresist, a Ti thin film was formed by a DC sputtering method (film thickness 100 nm). A method for forming the Ti thin film for a source-drain electrode is the same as that in the case of the gate electrode described above. Next, an unnecessary photoresist was removed with an ultrasonic washing apparatus in acetone to give TFT with a channel length of 10 μm and a channel width of 200 μm.

After the source-drain electrode was formed as described, a passivation layer was formed to protect each oxide semiconductor layer. As the passivation layer, a layered film (total film thickness 400 nm) of SiO₂ (film thickness 200 nm) and SiN (film thickness 200 nm) was used. The above-mentioned SiO₂ and SiN were formed by a plasma CVD method using “PD-220NL” manufactured by SAMCO Inc. In this example, after plasma treatment was carried out by N₂O gas, the SiO₂ film and the SiN film were successively formed. A mixed gas of N₂O and N₂ diluted SiH₄ was used for the formation of the SiO₂ film and a mixed gas of N₂ diluted SiH₄, N₂ and NH₃ was used for the formation of the SiN film. In both cases, the film formation power was set to 100 W and the film formation temperature was set to 150° C.

Next, a contact hole for probing for evaluating transistor characteristics was formed in the passivation layer by photolithography and dry etching. Next, an ITO film (film thickness 80 nm) was formed using a DC sputtering method in conditions as follows: carrier gas: mixed gas of argon gas and oxygen gas, film formation power: 200 W, and gas pressure: 5 mTorr, to produce a TFT shown in FIG. 1.

Each TFT obtained as described above was subjected to investigations as follows.

(1) Measurement of Transistor Characteristics

The transistor characteristics (drain current-gate voltage characteristics, Id-Vg characteristics) were measured using a semiconductor parameter analyzer (“4156C” manufactured by Agilent Technologies). The detailed measurement conditions were as follows. In this example, the ON current (Ion) at Vg=20 V was read and the pass criterion was that Ion≧1×10⁻⁵A.

Source voltage: 0 V

Drain voltage: 10V

Gate voltage: −30 to 30V (measurement interval: 0.25V)

(2) Threshold Voltage (Vth)

The threshold voltage is roughly a value of gate voltage at the time when a transistor is shifted from OFF state (state where drain current is low) to ON state (state where drain current is high). In this example, the voltage in the case where the drain current is over 1 nA between ON-current and OFF-current is defined as the threshold voltage, and the threshold voltage of each TFT was measured. In this example, the pass criterion was that Vth (absolute value) is 5V or less.

(3) S Value

The S value (SS value) was defined as the minimum value of the gate voltage necessary for increasing the drain current by one digit. In this example, the pass criterion was that S value is 1.0 V/dec or less.

(4) Carrier Mobility (Electron Field-Effect Mobility)

The carrier mobility (electron field-effect mobility) was calculated as the mobility in a saturation region according to the following expression. In this example, the pass criterion was that the saturation mobility of 5 cm²/Vs or higher.

$${I}_{d} = \frac{1}{2} {μ}_{FE} {C}_{OX} \frac{W}{L} {( {V}_{gs} - {V}_{th} )}^{2} \qquad [ Math 1 ]$$

Cox: insulator layer capacitance

W: channel width

L: channel length

Vth: threshold voltage

(5) Evaluation of Stress Stability (Light Irradiation and Negative Bias Application as Stress)

In this example, stress tests were carried out by irradiation of light while applying negative bias to a gate electrode for simulation of environments (stress) at the time of actual panel drive. The stress tests conditions were as follows. A light wavelength with about 400 nm was selected which was close to the band gap of an oxide semiconductor and with which the transistor characteristics tend to be easily fluctuated.

Gate voltage: −20V

Substrate temperature: 60° C.

Light stress

Wavelength: 400 nm

Illuminance (light intensity for irradiation to TFT): 0.1 μW/cm²

Light source: LED manufactured by OptoSupply Limited (light quantity was adjusted by an ND filter)

Stress tests time: 3 hour

Specifically, the threshold voltages (Vth) before and after the stress tests were measured using the technique described above, and a difference therebetween (ΔVth) was determined. In this example, the pass criterion was that the threshold voltage shift (the absolute value of ΔVth) of LNBTS is −15 V or less.

These results are shown in Table 1 and Table 2.

TABLE 1

| | | | | | [X]/ | [In]/ | | | |
|---|---|---|---|---|---|---|---|---|---|
| | | ratio to [In] + | | | ([In] + [Zn] + | ([Zn] + [Sn] + | [Zn]/ | | |
| | Oxide | [Zn] + [Sn] | | | [Sn] + [X]) | [In]) | ([Zn] + [Sn]) | [Sn]/ | \textcircled{2}* |
| No. | (Remarks) | [In] | [Zn] | [Sn] | ratio of[X] | \textcircled{1}***** | <Zn> | ([Zn] + [Sn]) | \textcircled{1} ≧ \textcircled{2} |
| 1 | IZTO + Si | 0.10 | 0.30 | 0.50 | 0.01 | 0.10 | 0.33 | 0.67 | 0.19 |
| 2 | | 0.05 | 0.90 | 0.05 | 0.02 | 0.05 | 0.95 | 0.05 | −0.14 |
| 3 | | 0.10 | 0.76 | 0.14 | 0.02 | 0.10 | 0.85 | 0.15 | −0.08 |
| 4 | | 0.10 | 0.54 | 0.35 | 0.02 | 0.10 | 0.60 | 0.40 | 0.04 |
| 5 | | 0.15 | 0.64 | 0.21 | 0.05 | 0.15 | 0.75 | 0.25 | −0.04 |
| 6 | | 0.20 | 0.52 | 0.28 | 0.05 | 0.20 | 0.65 | 0.35 | 0.02 |
| 7 | | 0.30 | 0.45 | 0.25 | 0.10 | 0.30 | 0.65 | 0.35 | 0.02 |
| 8 | IZTO + Hf | 0.20 | 0.20 | 0.50 | 0.02 | 0.20 | 0.25 | 0.75 | 0.23 |
| 9 | | 0.10 | 0.87 | 0.03 | 0.01 | 0.10 | 0.97 | 0.03 | −0.15 |
| 10 | | 0.10 | 0.87 | 0.23 | 0.01 | 0.10 | 0.75 | 0.25 | −0.04 |
| 11 | | 0.15 | 0.51 | 0.34 | 0.02 | 0.15 | 0.60 | 0.40 | 0.04 |
| 12 | | 0.20 | 0.52 | 0.28 | 0.02 | 0.20 | 0.85 | 0.35 | 0.02 |
| 13 | | 0.30 | 0.35 | 0.35 | 0.10 | 0.30 | 0.50 | 11.00 | 0.10 |
| 14 | IZTO + Ga | 0.05 | 0.57 | 0.38 | 0.10 | 0.05 | 0.60 | 0.40 | 0.04 |
| 15 | | 0.05 | 0.66 | 0.29 | 0.15 | 0.05 | 0.70 | 0.30 | −0.01 |
| 16 | | 0.10 | 0.45 | 0.45 | 0.05 | 0.10 | 0.50 | 0.50 | 0.10 |
| 17 | | 0.10 | 0.54 | 0.38 | 0.10 | 0.10 | 0.60 | 0.40 | 0.04 |
| 18 | | 0.15 | 0.64 | 0.21 | 0.15 | 0.15 | 0.75 | 0.25 | −0.04 |
| 19 | | 0.15 | 0.425 | 0.425 | 0.20 | 0.15 | 0.50 | 0.50 | 0.10 |
| 20 | | 0.20 | 0.52 | 0.28 | 0.25 | 0.20 | 0.65 | 0.35 | 0.02 |
| 21 | | 0.20 | 0.48 | 0.32 | 0.30 | 0.20 | 0.50 | 0.40 | 0.04 |
| 22 | | 0.30 | 0.35 | 0.35 | 0.35 | 0.30 | 0.50 | 0.50 | 0.10 |

| | Oxide | \textcircled{3}** | \textcircled{4}*** | saturation | absence of light Irradiation | | | | \textcircled{5}**** |
|---|---|---|---|---|---|---|---|---|---|
| No. | (Remarks) | \textcircled{1} ≧ \textcircled{3} | \textcircled{1} ≦ \textcircled{4} | mobility | Ion (A) | S (V/dec) | Vth (V) | ΔVth (V) | \textcircled{5} ≧ 5 |
| 1 | IZTO + Si | −1.26 | 0.04 | 17 | 0.005 | 1.2 | −17 | — | 5 |
| 2 | | 0.16 | 0.73 | 2 | 0.0004 | 0.9 | −11 | — | 15 |
| 3 | | −0.07 | 0.62 | 13 | 0.001 | 0.4 | 1 | −7 | 13 |
| 4 | | −0.64 | 0.34 | 9 | 0.001 | 0.4 | 0 | −5 | 9 |
| 5 | | −0.20 | 0.51 | 10 | 0.001 | 0.3 | 0 | −5 | 10 |
| 6 | | −0.53 | 0.40 | 9 | 0.001 | 0.3 | −1 | −6 | 9 |
| 7 | | −0.53 | 0.40 | 7 | 0.001 | 0.3 | −2 | −8 | 7 |
| 8 | IZTO + Hf | −1.44 | −0.05 | 14 | 0.005 | 1.2 | −20 | — | 9 |
| 9 | | 0.20 | 0.75 | 3 | 0.0005 | 0.5 | −8 | — | 18 |
| 10 | | −0.30 | 0.51 | 12 | 0.001 | 0.4 | 2 | −6 | 12 |
| 11 | | −0.64 | 0.34 | 9 | 0.001 | 0.4 | 2 | −8 | 9 |
| 12 | | −0.53 | 0.40 | 11 | 0.001 | 0.5 | 1 | −10 | 11 |
| 13 | | −0.87 | 0.23 | 3 | 0.000 | 0.6 | 2 | −15 | 3 |
| 14 | IZTO + Ga | −0.64 | 0.34 | 9 | 0.002 | 0.4 | −1 | −6 | 9 |
| 15 | | −0.41 | 0.45 | 11 | 0.002 | 0.4 | −1 | −5 | 11 |
| 16 | | −0.87 | 0.23 | 9 | 0.002 | 0.4 | 0 | −8 | 9 |
| 17 | | −0.64 | 0.34 | 10 | 0.002 | 0.4 | −1 | −7 | 10 |
| 18 | | −0.30 | 0.51 | 12 | 0.003 | 0.4 | −1 | −8 | 12 |
| 19 | | −0.87 | 0.23 | 9 | 0.003 | 0.5 | −2 | −10 | 9 |
| 20 | | −0.53 | 0.40 | 11 | 0.004 | 0.5 | −3 | −8 | 11 |
| 21 | | −0.64 | 0.24 | 11 | 0.004 | 0.5 | −4 | −12 | 11 |
| 22 | | −0.87 | 0.23 | 13 | 0.005 | 0.6 | −4 | −16 | 13 |

*Value on the right side of expression \textcircled{1}
**Value on the right side of expression \textcircled{2}
***Value on the right side of expression \textcircled{3}
****Value on the left side of expression \textcircled{4}
*****Value on the left side of expressions \textcircled{1} to \textcircled{3}

TABLE 2

| | | | | | [X]/ | [In]/ | | | |
|---|---|---|---|---|---|---|---|---|---|
| | | ratio to [In] + | | | ([In] + [Zn] + | ([Zn] + [Sn] + | [Zn]/ | | |
| | Oxide | [Zn] + [Sn] | | | [Sn] + [X]) | [In]) | ([Zn] + [Sn]) | [Sn]/ | \textcircled{2}* |
| No. | (Remarks) | [In] | [Zn] | [Sn] | ratio of [X] | \textcircled{1}***** | <Zn> | ([Zn] + [Sn]) | \textcircled{1} ≧ \textcircled{2} |
| 23 | IZTO + Al | 0.05 | 0.57 | 0.38 | 0.01 | 0.05 | 0.90 | 0.40 | 0.04 |
| 24 | | 0.10 | 0.67 | 0.23 | 0.01 | 0.10 | 0.75 | 0.25 | −0.04 |
| 25 | | 0.15 | 0.425 | 0.425 | 0.02 | 0.15 | 0.50 | 0.50 | 0.10 |
| 26 | | 0.20 | 0.52 | 0.28 | 0.02 | 0.20 | 0.85 | 0.35 | 0.02 |
| 27 | | 0.30 | 0.42 | 0.28 | 0.03 | 0.30 | 0.80 | 0.40 | 0.04 |
| 28 | | 0.30 | 0.58 | 0.11 | 0.03 | 0.30 | 0.85 | 0.15 | −0.09 |
| 29 | IZTO + Ni | 0.05 | 0.62 | 0.33 | 0.02 | 0.05 | 0.65 | 0.35 | 0.02 |
| 30 | | 0.10 | 0.47 | 0.23 | 0.02 | 0.10 | 0.75 | 0.25 | −0.04 |
| 31 | | 0.15 | 0.425 | 0.425 | 0.01 | 0.15 | 0.50 | 0.80 | 0.10 |
| 32 | | 0.20 | 0.48 | 0.32 | 0.01 | 0.20 | 0.50 | 0.40 | 0.04 |
| 33 | | 0.30 | 0.45 | 0.25 | 0.05 | 0.30 | 0.65 | 0.25 | 0.02 |
| 34 | IZTO + Ga | 0.15 | 0.30 | 0.55 | 0.01 | 0.15 | 0.35 | 0.65 | 0.17 |
| 35 | | 0.07 | 0.90 | 0.03 | 0.02 | 0.07 | 0.97 | 0.03 | −0.15 |
| 36 | | 0.05 | 0.71 | 0.24 | 0.01 | 0.05 | 0.75 | 0.25 | −0.04 |
| 37 | | 0.10 | 0.54 | 0.36 | 0.02 | 0.10 | 0.50 | 0.40 | 0.04 |
| 38 | | 0.15 | 0.64 | 0.21 | 0.02 | 0.15 | 0.75 | 0.25 | −0.04 |
| 39 | | 0.20 | 0.40 | 0.40 | 0.02 | 0.20 | 0.50 | 0.50 | 0.10 |
| 40 | | 0.30 | 0.56 | 0.14 | 0.20 | 0.30 | 0.20 | 0.20 | −0.06 |
| 41 | IZTO + Ta | 0.05 | 0.71 | 0.24 | 0.01 | 0.05 | 0.76 | 0.25 | −0.04 |
| 42 | | 0.10 | 0.58 | 0.32 | 0.01 | 0.10 | 0.65 | 0.35 | 0.02 |
| 43 | | 0.15 | 0.51 | 0.34 | 0.02 | 0.15 | 0.60 | 0.40 | 0.04 |
| 44 | | 0.20 | 0.40 | 0.40 | 0.02 | 0.20 | 0.50 | 0.50 | 0.10 |
| 45 | | 0.30 | 0.42 | 0.28 | 0.05 | 0.30 | 0.60 | 0.40 | 0.04 |
| 46 | | 0.30 | 0.42 | 0.28 | 0.05 | 0.30 | 0.60 | 0.40 | 0.04 |
| 47 | IZTO + W | 0.10 | 0.63 | 0.27 | 0.01 | 0.05 | 0.70 | 0.30 | −0.01 |
| 48 | | 0.10 | 0.58 | 0.32 | 0.01 | 0.10 | 0.65 | 0.35 | 0.02 |
| 49 | | 0.15 | 0.64 | 0.21 | 0.20 | 0.15 | 0.75 | 0.25 | −0.04 |
| 50 | IZTO + Nb | 0.10 | 0.30 | 0.60 | 0.02 | 0.10 | 0.33 | 0.67 | 0.19 |
| 51 | | 0.10 | 0.90 | 0 | 0.01 | 0.10 | 1.00 | 0.00 | −0.17 |
| 52 | | 0.05 | 0.71 | 0.24 | 0.01 | 0.05 | 0.75 | 0.25 | −0.04 |
| 53 | | 0.10 | 0.58 | 0.32 | 0.01 | 0.10 | 0.65 | 0.35 | 0.02 |
| 54 | | 0.15 | 0.51 | 0.34 | 0.02 | 0.15 | 0.60 | 0.40 | 0.04 |
| 55 | | 0.20 | 0.40 | 0.40 | 0.02 | 0.20 | 0.50 | 0.50 | 0.10 |
| 56 | | 0.30 | 0.42 | 0.28 | 0.05 | 0.30 | 0.60 | 0.40 | 0.04 |
| 57 | | 0.30 | 0.42 | 0.28 | 0.05 | 0.30 | 0.60 | 0.40 | 0.04 |

| | Oxide | \textcircled{3}** | \textcircled{4}*** | saturation | absence of light Irradiation | | | | \textcircled{5}**** |
|---|---|---|---|---|---|---|---|---|---|
| No. | (Remarks) | \textcircled{1} ≧ \textcircled{3} | \textcircled{1} ≦ \textcircled{4} | mobility | Ion (A) | S (V/dec) | Vth (V) | ΔVth (V) | \textcircled{5} ≧ 5 |
| 23 | IZTO + Al | −0.54 | 0.34 | 8 | 0.001 | 0.4 | 1 | −6 | 8 |
| 24 | | −0.30 | 0.51 | 12 | 0.001 | 0.4 | 1 | −5 | 12 |
| 25 | | −0.87 | 0.23 | 8 | 0.001 | 0.5 | 2 | −8 | 8 |
| 26 | | −0.53 | 0.40 | 10 | 0.001 | 0.5 | 1 | −6 | 11 |
| 27 | | −0.54 | 0.34 | 11 | 0.001 | 0.5 | 0 | −11 | 11 |
| 28 | | −0.07 | 0.52 | 10 | 0.001 | 0.4 | −1 | −10 | 11 |
| 29 | IZTO + Ni | −0.53 | 0.40 | 10 | 0.001 | 0.3 | 1 | −5 | 11 |
| 30 | | −0.30 | 0.61 | 13 | 0.001 | 0.4 | 2 | −7 | 12 |
| 31 | | −0.87 | 0.23 | 10 | 0.001 | 0.4 | 2 | −8 | 12 |
| 32 | | −0.54 | 0.34 | 12 | 0.001 | 0.3 | 1 | −9 | 10 |
| 33 | | −0.53 | 0.40 | 14 | 0.000 | 0.3 | 0 | −12 | 15 |
| 34 | IZTO + Ga | −1.21 | 0.07 | 17 | 0.005 | 1.1 | −18 | — | 8 |
| 35 | | 0.20 | 0.75 | 1 | 0.0003 | 1.2 | −10 | — | 15 |
| 36 | | −0.30 | 0.51 | 10 | 0.001 | 0.4 | 0 | −1 | 8 |
| 37 | | −0.64 | 0.34 | 6 | 0.001 | 0.4 | 0 | −7 | 6 |
| 38 | | −0.30 | 0.51 | 8 | 0.001 | 0.3 | −1 | −7 | 8 |
| 39 | | −0.87 | 0.23 | 7 | 0.001 | 0.3 | −2 | −12 | 7 |
| 40 | | −0.19 | 0.56 | 1 | 0.002 | 0.3 | −3 | −13 | −34 |
| 41 | IZTO + Ta | −0.30 | 0.51 | 12 | 0.001 | 0.4 | 1 | −3 | 12 |
| 42 | | −0.53 | 0.40 | 11 | 0.001 | 0.4 | 1 | −5 | 11 |
| 43 | | −0.54 | 0.34 | 10 | 0.001 | 0.5 | 2 | −8 | 10 |
| 44 | | −0.87 | 0.23 | 10 | 0.001 | 0.5 | 1 | −10 | 10 |
| 45 | | −0.54 | 0.34 | 11 | 0.001 | 0.6 | 2 | −12 | 11 |
| 46 | | −0.64 | 0.34 | 11 | 0.001 | 0.6 | 2 | −12 | 11 |
| 47 | IZTO + W | −0.41 | 0.45 | 6 | 0.001 | 0.4 | 1 | −3 | 8 |
| 48 | | −0.53 | 0.40 | 5 | 0.001 | 0.4 | 1 | −4 | 6 |
| 49 | | −0.30 | 0.51 | 1 | 0.000 | 0.5 | 2 | −7 | −103 |
| 50 | IZTO + Nb | −1.26 | 0.04 | 15 | 0.005 | 1.1 | −15 | — | 3 |
| 51 | | 0.27 | 0.78 | 2 | 0.0002 | 1.5 | −12 | — | 15 |
| 52 | | −0.30 | 0.51 | 11 | 0.001 | 0.4 | 1 | −5 | 11 |
| 53 | | −0.53 | 0.40 | 10 | 0.001 | 0.4 | 1 | −4 | 10 |
| 54 | | −0.54 | 0.34 | 8 | 0.001 | 0.5 | 2 | −3 | 8 |
| 55 | | −0.87 | 0.23 | 9 | 0.001 | 0.5 | 1 | −3 | 9 |
| 56 | | −0.64 | 0.34 | 7 | 0.001 | 0.6 | 2 | −5 | 7 |
| 57 | | −0.64 | 0.34 | 7 | 0.001 | 0.6 | 2 | −7 | 7 |

*Value on the right side of expression \textcircled{1}
**Value on the right side of expression \textcircled{2}
***Value on the right side of expression \textcircled{3}
****Value on the left side of expression \textcircled{4}
*****Value on the left side of expressions \textcircled{1} to \textcircled{3}

In Table 1, Nos. 1 to 7 additionally contain Si as the X-group element, Nos. 8 to 13 additionally contain Hf as the X-group element, and Nos. 14 to 22 additionally contain Ga as the X-group element. In Table 2, Nos. 23 to 28 additionally contain Al as the X-group element, Nos. 29 to 33 additionally contain Ni as the X-group element, Nos. 34 to 40 additionally contain Ge as the X-group element, Nos. 41 to 46 additionally contain Ta as the X-group element, Nos. 47 to 49 additionally contain W as the X-group element, and Nos. 50 to 57 additionally contain Nb as the X-group element. Some of these examples for which the values on the right sides of expressions (1) to (3) satisfy the respective relationships represented by expressions (1) to (3), and the value on the left side of expression (4) satisfies the relationship represented by expression (4), had excellent TFT characteristics including mobility, and had ΔVth which was suppressed to a predetermined range, and therefore, had excellent stress stability.

In contrast to this, examples described below have drawbacks described below.

No. 1 (Si added example) in Table 1 is an example which does not satisfy expressions (1) and (3), resulting in an increase in the Sn ratio, and in which the S value and the Vth value increased and the TFT characteristics decreased. The present invention is intended to simultaneously obtain both satisfactory TFT characteristics and satisfactory stress stability. TFTs having unsatisfactory TFT characteristics are not suitable for use even if their stress stability is satisfactory. Therefore, for the above example, the stress stability test was not conducted (“−” is shown in the ΔVth (V) column in Table 1, and the same applies to other examples below).

Also, No. 2 (Si added example) in Table 1 is an example which does not satisfy expression (2) and has a large Zn ratio, and in which the mobility sharply decreased and the Vth value significantly increased. Therefore, the stress stability test was not conducted.

No. 8 (Hf added example) in Table 1 is an example which does not satisfy expressions (1) and (3), resulting in an increase in the Sn ratio, and in which the S value and the Vth value increased and the TFT characteristics decreased. Therefore, the stress stability test was not conducted.

Also, No. 9 (Hf added example) in Table 1 is an example which does not satisfy expression (2) and has a large Zn ratio, and in which the mobility sharply decreased and the Vth value significantly increased. Therefore, the stress stability test was not conducted.

Also, No. 13 (Hf added example) in Table 1 is an example which does not satisfy expressions (4) and (3), resulting in decrease in the mobility. In addition, even though No. 13 does not satisfy expression (3), because of the content of Hf added was relatively large ([X] ratio=0.10), the stress stability satisfied the pass criterion (ΔVth is −15 V or less).

No. 22 (Ga added example) in Table 1 is an example which does not satisfy expression (3) and has a large In ratio, and in which the stress stability decreased.

No. 34 (Ge added example) in Table 2 is an example which does not satisfy expressions (1) and (3) and has a large Sn ratio, and in which the S valune and the Vth value decreased. Therefore, the stress stability test was not conducted.

No. 35 (Ge added example) in Table 2 is an example which does not satisfy expression (2) and has a large Zn ratio, and in which the Vth value significantly increased. Therefore, the stress stability test was not conducted.

No. 40 (Ge added example) in Table 2 is an example which does not satisfy expression (4) and has the saturation mobility decreased.

No. 49 (W added example) in table 2 is an example which does not satisfy expression (4) and has the saturation mobility decreased.

No. 50 (Nb added example) in Table 2 is an example which does not satisfy expressions (1), (3) and (4) and has a large Sn ratio, and in which the TFT characteristics of the S value and the Vth value. Therefore, the stress stability test was not conducted.

No. 51 (Nb added example) in Table 2 is an example which does not satisfy expression (2) and has a large Zn ratio, and in which the mobility sharply decreased and the Vth value significantly increased. Therefore, the stress stability test was not conducted.

The above experiment results show that the use of the IZTO semiconductor having the composition ratio defined by the present invention can provide significantly higher stress stability and satisfactory TFT characteristics while maintaining the mobility as high as that of conventional ZTO. Also, the semiconductor was satisfactorily processed by wet etching. Therefore, it is inferred that the oxide of the present invention may have an amorphous structure.

### Example 2

In this example, the densities of oxide films (film thickness 100 nm) formed by using an oxide with the composition corresponding to No. 6 in Table 1 (Si was used as X-group, InZnSnO+5.0% Si; [In]:[Zn]:[Sn]=0.20:0.52:0.28) and controlling the gas pressure at the time of sputtering film formation to 1 mTorr or 5 mTorr were measured, and the mobility and the change quantity (ΔVth) of threshold voltage after the stress test (light irradiation+negative bias application) were investigated for a TFT produced in the same manner as in Example 1 described above. A method for measuring the film density is as follows.

### (Measurement of Density of Oxide Film)

The density of the oxide film was measured by XRR (X-ray reflectivity method). The detailed measurement conditions were as follows.

Analysis apparatus: Horizontal type x-ray diffraction apparatus Smart Lab manufactured by Rigaku Co., Ltd.

Target: Cu (beam source: Kα ray)

Target output power: 45 kV-200 mA

Production of measurement sample

A sample used was produced by forming a film (film thickness 100 nm) of an oxide with each composition on a glass substrate in the following sputtering conditions, and thereafter carrying out the same heat treatment as that for pre-annealing treatment simulating the pre-annealing treatment in the TFT production process of Example 1 as described above.

Sputtering gas pressure: 1 mTorr or 5 mTorr

Oxygen partial pressure: O₂/(Ar+O₂)=2%

Film formation power density: DC 2.55 W/cm²

Heat treatment: 350° C. for 1 hour under an air atmosphere

These results are shown in Table 3.

TABLE 3

| | | Gas pressure at | | | |
|---|---|---|---|---|---|
| | | the time of film | | | |
| | | formation | Density | Movility | Δ Vth |
| No. | Composition | (mTorr) | (g/cm³) | (cm³/Vs) | (V) |
| 1 | Same as No. 6 in | 1 | 6.2 | 13.7 | −3.8 |
| 2 | Table 1 | 5 | 5.8 | 9.4 | −6.2 |

According to Table 3, the oxides satisfying all requirement defined by the present invention all showed a high density of 5.8 g/cm³ or higher. In particular, the film density at the time of a gas pressure of 5 mTorr (No. 2) was 5.8 g/cm³, whereas the film density at the time of a gas pressure of 1 mTorr (No. 1) was 6.2 g/cm³, and as the gas pressure was lowered, a higher density was obtained. Also, as the film density was increased, the electron field-effect mobility was improved and further more, the absolute value of ΔVth of the shift quantity of threshold value by the stress test was also lowered.

According to the experimental results, it was found that the density of the oxide film was changed in accordance with the gas pressure at the time of sputtering film formation, and if the gas pressure was lowered, the film density was increased and accordingly, the electron field-effect mobility was increased significantly and the absolute value of ΔVth of the shift quantity of threshold value by the stress test (light irradiation+negative bias stress) was decreased. That is supposedly attributed to that the disturbance of sputtered atoms (molecules) can be suppressed by lowering the gas pressure at the time of sputtering film formation to lessen the defects in the film, and thus the mobility and the electric conductivity are increased to improve the TFT stability.

Although Table 3 shows the results which were obtained when the oxide of No. 6 in Table 1 which contains Si as the X-group element was used, the above-described relationship between the density of the oxide film and the mobility in TFT characteristics or the amount of a threshold voltage change after the stress test was similarly observed for other oxides which contain the X-group element (s) other than Si and satisfy the preferable requirements defined in the present invention. Specifically, other oxide films which contain the X-group element (s) and satisfy the preferable requirements defined in the present invention all had a density of 5.8 g/cm³ or higher.

### EXPLANATION OF REFERENCE NUMERALS

1 Substrate
2 Gate electrode
3 Gate insulator layer
4 Oxide semiconductor layer
5 Source-drain electrode
6 Passivation layer (insulator layer)
7 Contact hole
8 Transparent conductive film

1. An oxide
comprising
Zn, Sn and In; and
at least one element X selected from the group consisting of Si, Hf, Ga, Al, Ni, Ge, Ta, and Nb.

2. The oxide according to claim 1, wherein a content in atomic % of Zn, Sn, and In is [Zn], [Sn], and [In] respectively, and [Zn], [Sn], and [In] satisfy expressions (1) to (3):
[In]/([In]+[Zn]+[Sn])≧−0.53×[Zn]/([Zn]+[Sn])+0.36 (1)
[In]/([In]+[Zn]+[Sn])≧2.28×[Zn]/([Zn]+[Sn])−2.01 (2)
[In]/([In]+[Zn]+[Sn])≦1.1×[Zn]/([Zn]+[Sn])−0.32 (3).

3. The oxide according to claim 1, wherein a content in atomic % of Zn, Sn, In, and X is [Zn], [Sn], [In], and [X] respectively, a ratio of a content in atomic % of each element X to ([Zn]+[Sn]+[In]+[X]) is represented by {X}, and expression (4) is satisfied:
[−89×<Zn>+74]×[In]/([In]+[Zn]+[Sn])+25×<Zn>−6.5−75×{Si}−120×{Hf}−6.5×{Ga}−123×{Al}−15×{Ni}−244×{Ge}−80×{Ta}−160×{Nb}≧5 (4)
wherein
<Zn>=[Zn]/([Zn]+[Sn]),
{Si}=[Si]/([Zn]+[Sn]+[In]+[X]),
{Hf}=[Hf]/([Zn]+[Sn]+[In]+[X]),
{Ga}=[Ga]/([Zn]+[Sn]+[In]+[X]),
{Al}=[Al]/([Zn]+[Sn]+[In]+[X]),
{Ni}=[Ni]/([Zn]+[Sn]+[In]+[X]),
{Ge}=[Ge]/([Zn]+[Sn]+[In]+[X]),
{Ta}=[Ta]/([Zn]+[Sn]+[In]+[X]), and
{Nb}=[Nb]/([Zn]+[Sn]+[In]+[X]).

4. The oxide according to claim 2, wherein a content in atomic % of Zn, Sn, In, and X is [Zn], [Sn], [In], and [X] respectively, a ratio of a content in atomic % of each element X to ([Zn]+[Sn]+[In]+[X]) is represented by {X}, and expression (4) is satisfied:
[−89×<Zn>+74]×[In]/([In]+[Zn]+[Sn])+25×<Zn>−6.5−75×{Si}−120×{Hf}−6.5×{Ga}−123×{Al}−15×{Ni}−244×{Ge}−80×{Ta}−160×{Nb}≧5 (4)
wherein
<Zn>=[Zn]/([Zn]+[Sn]),
{Si}=[Si]/([Zn]+[Sn]+[In]+[X]),
{Hf}=[Hf]/([Zn]+[Sn]+[In]+[X]),
{Ga}=[Ga]/([Zn]+[Sn]+[In]+[X]),
{Al}=[Al]/([Zn]+[Sn]+[In]+[X]),
{Ni}=[Ni]/([Zn]+[Sn]+[In]+[X]),
{Ge}=[Ge]/([Zn]+[Sn]+[In]+[X]),
{Ta}=[Ta]/([Zn]+[Sn]+[In]+[X]), and
{Nb}=[Nb]/([Zn]+[Sn]+[In]+[X]).

5. The oxide according to claim 1, wherein a content in atomic % of Zn, Sn, In, and X is [Zn], [Sn], [In], and [X] respectively, and [Zn], [Sn], [In], and [X] satisfy expression (5):
0.0001≦[X]/([Zn]+[Sn]+[In]+[X]) (5).

6. A thin-film transistor comprising the oxide according to claim 1 as a semiconductor layer of the thin-film transistor.

7. The thin-film transistor according to claim 6, wherein a density of the semiconductor layer is 5.8 g/cm³ or higher.

8. A sputtering target suitable for forming the oxide according to claim 1, wherein
the sputtering target comprises Zn, Sn and In; and at least one element X selected from the group consisting of Si, Hf, Ga, Al, Ni, Ge, Ta, and Nb, and
a content in atomic % of Zn, Sn, and In in the sputtering target is [Zn], [Sn], and [In] respectively, and [Zn], [Sn], and [In] satisfy expressions (1) to (3):
[In]/([In]+[Zn]+[Sn])≧−0.53×[Zn]/([Zn]+[Sn])+0.36 (1)
[In]/([In]+[Zn]+[Sn])≧2.28×[Zn]/([Zn]+[Sn])−2.01 (2)
[In]/([In]+[Zn]+[Sn])≦1.1×[Zn]/([Zn]+[Sn])−0.32 (3).

9. The sputtering target according to claim 8, wherein a content in atomic % of Zn, Sn, In, and X in the sputtering target is [Zn], [Sn], [In], and [X] respectively, a ratio of a content in atomic % of each element X to ([Zn]+[Sn]+[In]+[X]) is represented by {X}, and expression (4) is satisfied:
[−89×<Zn>+74]×[In]/([In]+[Zn]+[Sn])+25×<Zn>−6.5−75×{Si}−120×{Hf}−6.5×{Ga}−123×{Al}−15×{Ni}−244×{Ge}−80×{Ta}−160×{Nb}≧5 (4)
wherein,
<Zn>=[Zn]/([Zn]+[Sn]),
{Si}=[Si]/([Zn]+[Sn]+[In]+[X]),
{Hf}=[Hf]/([Zn]+[Sn]+[In]+[X]),
{Ga}=[Ga]/([Zn]+[Sn]+[In]+[X]),
{Al}=[Al]/([Zn]+[Sn]+[In]+[X]),
{Ni}=[Ni]/([Zn]+[Sn]+[In]+[X]),
{Ge}=[Ge]/([Zn]+[Sn]+[In]+[X]),
{Ta}=[Ta]/([Zn]+[Sn]+[In]+[X]), and
{Nb}=[Nb]/([Zn]+[Sn]+[In]+[X]).

10. The sputtering target according to claim 8, wherein a content in atomic % of Zn, Sn, In, and X in the sputtering target is [Zn], [Sn], [In], and [X] respectively, and [Zn], [Sn], [In], and [X] satisfy expression (5):
0.0001≦[X]/([Zn]+[Sn]+[In]+[X]) (5).

11. A thin-film transistor comprising the oxide according to claim 2 as a semiconductor layer of the thin-film transistor.

12. A thin-film transistor comprising the oxide according to claim 3 as a semiconductor layer of the thin-film transistor.

13. A thin-film transistor comprising the oxide according to claim 4 as a semiconductor layer of the thin-film transistor.

14. A thin-film transistor comprising the oxide according to claim 5 as a semiconductor layer of the thin-film transistor.

15. The thin-film transistor according to claim 11, wherein a density of the semiconductor layer is 5.8 g/cm³ or higher.

16. The thin-film transistor according to claim 12, wherein a density of the semiconductor layer is 5.8 g/cm³ or higher.

17. The thin-film transistor according to claim 13, wherein a density of the semiconductor layer is 5.8 g/cm³ or higher.

18. The thin-film transistor according to claim 14, wherein a density of the semiconductor layer is 5.8 g/cm³ or higher.
